(19) United States
(12) Patent Application Publication
(10) Pub. No.: US 2026/0307982 A1
(43) Pub. Date: Oct. 8, 2026

(54) PACKAGING METHOD FOR MEMS ACOUSTIC DEVICE STRUCTURE, MEMS ACOUSTIC DEVICE PACKAGING STRUCTURE AND MEMS CHIP PACKAGING METHOD FOR ACOUSTIC DEVICE

(71) Applicant: HEFEI SMAT TECHNOLOGY CO. LTD., HEFEI CITY (CN)

(72) Inventor: Xiaochun TAN, HEFEI CITY (CN)

(21) Appl. No.: 19/634,234

(22) Filed: Mar. 31, 2026

(30) Foreign Application Priority Data
Apr. 7, 2025 (CN) 202510423153.5
Apr. 7, 2025 (CN) 202510423220.3
Apr. 7, 2025 (CN) 202510423221.8

(51) Int. Cl. B81C 1/00; B81B 7/00

(52) U.S. Cl. CPC B81C 1/0023; B81B 7/008; B81B 2201/0257; B81B 2203/0127; B81B 2207/012; B81B 2207/07; B81C 2203/0109; B81C 2203/0792

(57) ABSTRACT

A MEMS acoustic device packaging method, a packaging structure of a MEMS acoustic device structure, and a MEMS chip packaging method for an acoustic device are disclosed. The MEMS acoustic device packaging method comprises: first device encapsulation: encapsulating a first device, plating a redistribution layer, plating a conductive block, and encapsulating and exposing a top surface of the conductive block to form a package body; second device interconnection: electrically connecting a second device to the conductive block, with the second device and the first device being vertically stacked and connected; substrate ring mounting: mounting a substrate ring; cover plate packaging: mounting a cover plate. The present disclosure achieves vertical stacking of the two device structures by soldering the second device onto the first device without using a wire bonding process, saving stacking space, resulting in higher integration, smaller size, better structural stability, and more stable and reliable line transmission.

### CROSS-REFERENCE TO RELATED APPLICATIONS

This present disclosure claims priority to a Chinese patent application No. 202510423221.8, filed on Apr. 07, 2025, and entitled "Packaging Method for MEMS Acoustic Device Structure", a Chinese patent application No. 202510423153.5, filed on Apr. 07, 2025, and entitled "MEMS Acoustic Device Packaging Structure", and Chinese patent application No. 202510423220.3, filed on Apr. 07, 2025, and entitled "MEMS Chip Packaging Method for Acoustic Device", the entire contents of which are incorporated herein by reference, comprising the specification, claims, drawings and abstract.

### FIELD OF TECHNOLOGY

The present disclosure relates to a field of sensors, particularly, to a packaging method for a MEMS acoustic device structure, a MEMS acoustic device packaging structure and a MEMS chip packaging method for an acoustic device.

### BACKGROUND

Micro-Electro-Mechanical System (MEMS) technology is currently the most popular sensor manufacturing technology, and is also an important driving force for the miniaturization, intelligence, and low power consumption of sensors. MEMS technology has greatly promoted the development of sensors. MEMS mainly adopts microelectronic technology to shape the mechanical structure of sensors at micro-nanometer scales. A MEMS sensor is a device formed by packaging a MEMS chip (second device) and an application specific integrated circuit chip (first device) together. The second device converts sound into capacitance, resistance, and other signal changes, and the first device converts capacitance, resistance, and other signal changes into electrical signals, thereby realizing the function of the MEMS sensor—converting external signals into electrical signals. MEMS acoustic sensors mainly refer to silicon microphones, ultrasonic sensors, and the like.

In existing acoustic sensors, the second device and the first device are arranged side by side, and the electrode of the second device is above the substrate. Metal wires are connected between the second device and the first device through a wire bonding process to achieve electrical connection therebetween. Such a structural arrangement results in excessively large sensor dimensions.

Chinese Patent Publication No. CN221319324U discloses a MEMS packaging structure and a MEMS acoustic sensor comprising the same. The MEMS packaging structure comprises: a third substrate; a first substrate having an acoustic inlet hole formed thereon; and a second substrate having a hollow ring shape, sandwiched between the first substrate and the third substrate; wherein, in a device mounting space, the second device is fixed on the first substrate with its back cavity facing the acoustic inlet hole; the first device is fixed on the third substrate; an electrical signal conductive pillar for signal transmission is formed longitudinally inside the second substrate, and an induction signal of the second device is transmitted to the first device through the electrical signal conductive pillar, thereby omitting the traditional wire bonding process while still achieving signal interconnection between chips and between chips and the substrate, thus greatly reducing the volume of the packaged device and meeting the demand for higher circuit integration. However, this technology requires the use of three substrates, and circuit need to be provided inside each substrate; the second device still requires a wire bonding process to achieve electrical connection with the circuit inside the substrate; the first device and its electrical structure are exposed, affecting service life; the process is complex; and the integration is low.

Furthermore, the core of the MEMS acoustic sensor is the MEMS chip. The diaphragm of the MEMS chip undergoes mechanical vibration due to acoustic wave impact, causing changes in electrical values. Electrodes of existing MEMS chips are generally provided on the front surface of the chip, that is, on the surface of the substrate where the diaphragm is located. The diaphragm requires mechanical vibration space, resulting in poor flexibility for leading out electrical connections from the electrical connection terminals of the MEMS chip. When connecting the MEMS chip with an ASIC chip, it is often achieved by wire bonding between the front electrode and the ASIC chip, resulting in excessively large structural dimensions that fail to meet the requirements for device miniaturization. When the MEMS chip is electrically connected to other devices via metal wire traction from the front electrode, the extremely thin diaphragm is easily damaged, and the electrical connection process is difficult.

### SUMMARY OF THE DISCLOSURE

In view of the above problems, an object of the present disclosure is to provide a MEMS acoustic device packaging method, a packaging structure of a MEMS acoustic device structure, and a MEMS chip packaging method for an acoustic device.

To achieve the above object, a packaging method for a MEMS acoustic device structure proposed by the present disclosure comprises steps of:

first device encapsulation: encapsulating a first device and exposing an electrical interface, plating a redistribution layer on an encapsulation surface to be connected with the electrical interface, plating a conductive block on a portion of the redistribution layer, and encapsulating and exposing a top surface of the conductive block to form a package body;

second device interconnection: electrically connecting a second device to the conductive block, with the second device and the first device being vertically stacked and connected;

substrate ring mounting: mounting a substrate ring on the package body to enclose the second device;

cover plate packaging: mounting a cover plate to seal the substrate ring, with an acoustic hole of the cover plate aligned with a middle portion of a diaphragm of the second device.

Further, in the step of first device encapsulation, the first device is placed on a carrier board, and before plating the redistribution layer on an encapsulation top surface exposing the electrical interface after encapsulating the first device, encapsulation material is vertically etched to a bottom of a drilled hole to expose the carrier board, and a metal pillar is plated to completely fill the drilled hole.

Further, in the step of first device encapsulation, a top end of the metal pillar is electrically connected to another portion of the redistribution layer, a bottom end of the metal pillar is in contact with the carrier board, and the first device is electronically connected to the bottom end of the metal pillar by the electrical interface through the redistribution layer.

Further, in the step of first device encapsulation, the bottom end of the metal pillar is flush with and exposed from a bottom surface of the package body, external pins are plated on a bottom surface of the package body where the metal pillar is exposed, and the bottom end of the metal pillar is electrically connected to portions of the external pins.

Further, in the step of first device encapsulation, after encapsulating with encapsulation material, the encapsulation surface is horizontally mechanically ground to respectively expose the electrical interface and the conductive block.

Further, in the step of second device interconnection, an electrode is covered above a substrate of the second device, and a diaphragm is covered above the electrode.

Further, in the step of second device interconnection, a pitch between the diaphragm and the electrode is 1-5 μm.

Further, in the step of second device interconnection, a material of the substrate is selected from one or more of flexible materials, glass, and semiconductor materials.

Further, a material of the diaphragm is selected from one or more of polysilicon, silicon nitride, and metals.

Further, in the step of second device interconnection, a middle portion of the substrate of the second device is etched through to form a back cavity located directly below the diaphragm, a circuit is provided inside the substrate of the second device, a solder pad is provided at a bottom of the substrate, a top end of the circuit is electrically connected to the electrode, and a bottom end of the circuit is electrically connected to the solder pad.

Further, in the step of second device interconnection, the solder pad of the second device is soldered to an exposed top surface of the conductive block of the package body by reflow soldering to form an integrated structure.

Further, in the step of second device interconnection, the diaphragm of the second device generates mechanical vibration, causing an electrical value change, which is transmitted sequentially through the electrode, the circuit, the solder pad, the conductive block, and the redistribution layer to the first device for signal processing.

Further, in the step of first device encapsulation, the first device is an ASIC chip.

Further, in the step of second device interconnection, the second device is a MEMS chip.

To achieve the above object, a MEMS acoustic device packaging structure proposed by the present disclosure, comprises a first device and a second device, and further comprises:

a redistribution layer plated inside a package body and connected to an electrical interface, a conductive block plated on a portion of the redistribution layer, with a top surface of the conductive block flush with and exposed from the package body;

a substrate ring mounted on the package body to enclose the second device; and

a cover plate mounted to seal the substrate ring, with an acoustic hole of the cover plate aligned with a middle portion of a diaphragm of the second device,

wherein the first device is encapsulated in the package body, and the second device is electrically connected to the conductive block, so as to be vertically stacked and connected with the first device.

Further, before plating the redistribution layer in the package body, the encapsulation material is vertically etched to a bottom surface of the package body, and a metal pillar is plated to completely fill [the etched opening].

Further, a top end of the metal pillar is electrically connected to another portion of the redistribution layer, and the first device is electrically connected to a bottom end of the metal pillar through the electrical interface via the redistribution layer.

Further, a bottom end of the metal pillar is flush with and exposed from a bottom surface of the package body, external pins are plated on the bottom surface of the package body where the metal pillar is exposed, and the bottom end of the metal pillar is electrically connected to portions of the external pins.

Further, an electrode is covered above a substrate of the second device, and a diaphragm is covered above the electrode.

Further, a pitch between the diaphragm and the electrode is 1-5 μm.

Further, a material of the substrate of the second device is selected from one or more of flexible materials, glass, and semiconductor materials.

Further, a material of the diaphragm is selected from one or more of polysilicon, silicon nitride, and metals.

Further, a middle portion of the substrate of the second device is etched through to form a back cavity located directly below the diaphragm, a circuit is provided inside the substrate of the second device, a solder pad is provided at a bottom of the substrate, a top end of the circuit is electrically connected to the electrode, and a bottom end of the circuit is electrically connected to the solder pad at the bottom of the substrate.

Further, the solder pad of the second device is soldered to an exposed top surface of the conductive block of the package body by reflow soldering to form an integrated structure.

Further, the diaphragm generates mechanical vibration, causing an electrical value change, which is transmitted sequentially through the electrode, the circuit, the solder pad, the conductive block, and the redistribution layer to the first device for signal processing.

Further, the first device is an ASIC chip.

Further, the second device is a MEMS chip.

Further, the substrate ring and the cover plate are bonded by an adhesive.

The present disclosure further proposes a MEMS sensor, comprising the above-mentioned MEMS acoustic device packaging structure.

To achieve the above object, a MEMS chip packaging method for an acoustic device proposed by the present disclosure comprises steps of:

substrate etching: an electrode being provided above a substrate, a diaphragm being provided above the electrode, etching through from a middle position of a surface of the substrate away from the electrode to form a back cavity, so as to expose the electrode, with the back cavity located directly below the electrode;

simultaneously etching through other portions of the substrate to form a circuit hole exposing the electrode;

circuit plating: plating and filling metal in the circuit hole to form a circuit, with one end of the circuit electrically connected to the electrode and the other end of the circuit flush with and exposed from the surface of the substrate.

Further, in the step of substrate etching, a material of the substrate is selected from one or more of flexible materials, glass, and semiconductor materials.

Further, in the step of substrate etching, an electrode is covered on the substrate, and the electrode has a porous structure.

Further, in the step of substrate etching, a diaphragm is covered on the electrode, and a pitch between the diaphragm and the electrode is 1-5 μm.

Further, in the step of substrate etching, a material of the diaphragm is selected from one or more of polysilicon, silicon nitride, and metals.

Further, in the step of circuit plating, a solder pad is extendedly plated on the surface of the substrate where the circuit is exposed, and the solder pad is electrically connected to the circuit.

Further, in the step of circuit plating, the diaphragm generates mechanical vibration, causing an electrical value change, which is transmitted sequentially through the electrode, the circuit, and the solder pad.

The present disclosure further provides a MEMS chip packaging structure for an acoustic device, comprising a substrate, and further comprising:

an electrode and a diaphragm, the electrode being provided above the substrate, and the diaphragm being provided above the electrode;

a back cavity, the back cavity being formed by etching through from a middle position of a surface of the substrate away from the electrode to expose the electrode, with the back cavity located directly below the diaphragm and the electrode;

a circuit, a circuit hole being formed by etching through other portions of the substrate, metal being plated and filled in the circuit hole to form the circuit, one end of the circuit being electrically connected to the electrode, and the other end of the circuit being flush with and exposed from a surface of the substrate.

Further, a material of the substrate is selected from one or more of flexible materials, glass, and semiconductor materials.

Further, an electrode is covered on the substrate, and the electrode has a porous structure.

Further, a diaphragm is covered on the electrode, and a pitch between the diaphragm and the electrode is 1-5 μm.

Further, a material of the diaphragm is selected from one or more of polysilicon, silicon nitride, and metals.

Further, a solder pad is extendedly plated on the surface of the substrate where the circuit is exposed, and the solder pad is electrically connected to the circuit.

Further, the diaphragm generates mechanical vibration, causing an electrical value change, which is transmitted sequentially through the electrode, the circuit, and the solder pad.

The present disclosure further provides an acoustic device, comprising the above-mentioned MEMS chip packaging structure for an acoustic device.

The beneficial effects of the present disclosure are: 1. The electrical property of the second device is led from the electrode on its front side to the solder pad on its back side, providing good mounting flexibility for the MEMS chip.

2. The first device is encapsulated in the package body, so that the ASIC chip is protected from erosion by the external environment, prolonging the service life, and the back side of the first device is exposed outside the package body through adhesive glue, enhancing heat dissipation performance.

3. The first device and the second device are processed separately and then mounted and stacked together, making the entire processing technology more efficient.

4. By soldering the solder pad of the second device to the conductive block of the package body of the first device, stacking of the two devices is achieved without using wire bonding technology, saving stacking space, achieving high integration of the entire structure, smaller size, good structural stability, and more stable and reliable line transmission.

5. By adding circuit plating and solder pad connected to the circuit after substrate etching during the MEMS chip manufacturing process, the electrical property of the MEMS chip is led from the electrode on its front side to the solder pad on its back side, providing better mounting flexibility for the MEMS chip, the circuit inside the substrate replace wire bonding technology, the entire structure of the chip is more compact, and the requirements for device miniaturization are satisfied.

### BRIEF DESCRIPTION OF THE DRAWINGS

FIGS. 1-5 are cross-sectional views of the step of substrate etching of a MEMS chip packaging method for an acoustic device according to the present disclosure;

FIGS. 6-8 are cross-sectional views of the step of circuit plating of a MEMS chip packaging method for an acoustic device according to the present disclosure;

FIG. 9 is a cross-sectional view of a MEMS chip packaging structure for an acoustic device according to the present disclosure;

FIGS. 10-16 are cross-sectional schematic views of a packaging step of a first device of a packaging method for a MEMS acoustic device structure according to the present disclosure;

FIG. 17 is a cross-sectional schematic view of the mounting of a first device and a second device of a packaging method for a MEMS acoustic device structure according to the present disclosure;

FIGS. 18-19 are cross-sectional schematic views of mounting of a substrate ring and a cover plate packaging of a packaging method for a MEMS acoustic device structure according to the present disclosure;

FIG. 20 is a cross-sectional view of a packaging structure obtained by a packaging method for a MEMS acoustic device structure according to the present disclosure;

FIG. 21 is a cross-sectional view of a second device obtained by a packaging method for a MEMS acoustic device structure according to the present disclosure.

In the drawings: 1. first device; 2. redistribution layer; 3. conductive block; 4. package body; 5. metal pillar; 6. external pin; 7. second device; 8. solder pad; 9. substrate; 10. circuit; 11. back cavity; 12. diaphragm; 13. substrate ring; 14. cover plate; 15. acoustic hole; 16. electrode.

### DETAILED DESCRIPTION OF THE DISCLOSURE

In order to make the objectives, technical solutions, and advantages of the present disclosure clearer, the technical solutions in the present disclosure will be clearly and completely described below with reference to the accompanying drawings in the present disclosure. Apparently, the described embodiments are part of the embodiments of the present disclosure, rather than all of the embodiments. Based on the embodiments in the present disclosure, all other embodiments obtained by those of ordinary skill in the art without making creative efforts shall fall within the protection scope of the present disclosure; the content of the present disclosure will be explained below in conjunction with specific embodiments, and examples of the embodiments are illustrated in the accompanying drawings, wherein the same or similar reference numerals denote the same or similar components or components having the same or similar functions throughout.

The terms "first", "second", and the like in the description and claims of the present disclosure and the above drawings are used for distinguishing similar objects, and are not necessarily used to describe a specific sequence or order. It should be understood that such used data may be interchanged under appropriate circumstances, so that the embodiments described herein can be implemented in an order other than that illustrated or described herein; the directional terms mentioned in the present disclosure, such as: upper, lower, left, right, front, rear, inner, outer, front side, back side, side, and the like, are only directions with reference to the drawings, and the embodiments described below with reference to the drawings and the directional terms used are exemplary, and are only used for explaining the present disclosure, and cannot be construed as limitations on the present disclosure. In addition, various examples of specific processes and materials provided by the present disclosure are those of which those skilled in the art may be aware of the present disclosure of other processes and/or the use of other materials.

In order to better understand the objectives, structure, and functions of the present disclosure, a MEMS acoustic device packaging methods, a packaging structure of a MEMS acoustic device structure, and a MEMS chip packaging method for an acoustic device proposed by the present disclosure will be further described in detail below with reference to the accompanying drawings.

The MEMS chip packaging method for an acoustic device proposed by the present disclosure comprises the following steps:

Substrate 9 etching: an electrode 16 is provided above a substrate 9, a diaphragm 12 is provided above the electrode 16, and the middle portion of the surface of the substrate 9 away from the electrode 16 is etched through to form a back cavity 11 to expose the electrode 16, the back cavity 11 being located directly below the electrode 16;

and simultaneously etching through other portions of the substrate 9 to form circuit hole exposing the electrode 16;

Circuit 10 plating: plating metal to fill the circuit hole to form a circuit 10, one end of the circuit 10 being electrically connected to the electrode 16, and the other end of the circuit 10 being flush with and exposed from the surface of the substrate 9.

The more specific processes of each process step are as follows:

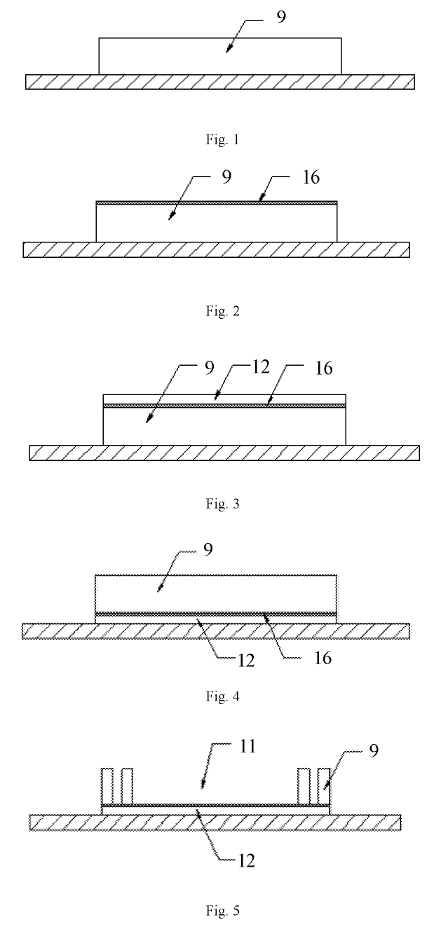

S101: providing a carrier plate, which may be a resin plate commonly used in the art, and placing the original substrate 9 for manufacturing a MEMS chip on the carrier plate (as shown in FIG. 1); the substrate 9 may be one or more of flexible materials, glass, and semiconductor materials, usually silicon, which has good mechanical properties, thermal stability, and good compatibility with micro-processing technology, the substrate 9 being located at the bottommost layer of the MEMS chip, serving as mechanical support for the entire structure, providing structural stability, and serving as a base for other components such as the electrode 16 and the back cavity 11.

S102: covering a layer of electrode 16 on the upper surface of the substrate 9 (as shown in FIG. 2), wherein the electrode 16 of the MEMS acoustic sensor is divided into a fixed electrode and a movable electrode, the fixed electrode being located above or below the diaphragm 12, parallel to the diaphragm 12, and fixed on the substrate 9, while the movable electrode is directly integrated on the surface of the diaphragm 12, and the diaphragm 12 itself may serve as an electrode, wherein in the present disclosure, the electrode 16 is covered on the upper surface of the substrate 9.

S103: continuing to cover the electrode 16 with a layer of diaphragm 12 (as shown in FIG. 3). In this embodiment, the electrode 16 is disposed below the diaphragm 12, and the electrode 16 is a fixed electrode designed with a porous structure to reduce air damping and allow sound waves to pass through. The pitch between the diaphragm 12 and the electrode 16 is approximately 1-5 μm, forming a variable capacitor. The diaphragm 12 is directly exposed to an external sound field. The material of the diaphragm 12 is selected from polysilicon, which has excellent characteristics such as high mobility comparable to single crystal silicon material, compatibility with amorphous silicon thin film growth processes, ease of achieving large-area growth, and low preparation cost, and is widely used in technical fields such as microelectronic devices. In addition, polysilicon film structures are also commonly used in micro-electro-mechanical systems (MEMS), particularly as basic vibration structures for sensor devices. The material of the diaphragm 12 may also be one or more of silicon nitride or metal. The diaphragm 12 on the MEMS chip is extremely thin, with a thickness in the nanometer to micrometer range, is sensitive to sound pressure, and its vibration displacement is proportional to the sound pressure, serving as the core sensitive element of the sensor.

S104: peeling the substrate 9 from the carrier board, and flipping it over and remounting it on the carrier board, such that the diaphragm 12 is in contact with the carrier board and the bottom of the substrate 9 faces upward (as shown in FIG. 4).

S105: vertically etching at a central position of the substrate 9 to expose the electrode 16, such that the substrate 9 becomes a ring-shaped structure with a hollow center, wherein the hollow portion is the back cavity 11 of the substrate 9. The back cavity 11 is located directly below the diaphragm 12, and is generally cylindrical or rectangular; this embodiment takes a cylindrical shape as an example. The depth of the back cavity 11 is determined by the acoustic sensitivity and frequency response requirements of the specific product. The back cavity 11 structure allows the diaphragm 12 to vibrate freely under sound pressure, avoids air damping, and can balance the pressure on both sides of the diaphragm 12. Simultaneously, the remaining cylindrical ring portion of the substrate 9 is vertically etched to likewise expose the electrode 16 (as shown in FIG. 5). Since the substrate 9 may be one or more of flexible material, glass, or semiconductor material, typically silicon, during etching, a protective film is coated on the surface of the substrate 9 to be etched, with positions requiring etching left uncoated for protection. In the present disclosure, anisotropic vertical etching relative to the surface of the substrate 9 is adopted, wherein the etching penetrates from the surface of the substrate 9 through to the upper surface of the electrode 16, exposing the surface of the electrode 16.

The etching may be performed by laser etching, dry etching, or other etching methods. Vertical through-holes are formed in the substrate by etching, wherein the through-holes are used for vertical interconnection in multi-layer stacked packaging, such as circuit plated within circuit hole. This embodiment takes laser ablation (LaS10er Ablation) as an example, the principle of which is: utilizing a high-energy laser beam to directly ablate material without requiring a mask, and controlling the etching conditions by adjusting parameters such as laser irradiation frequency.

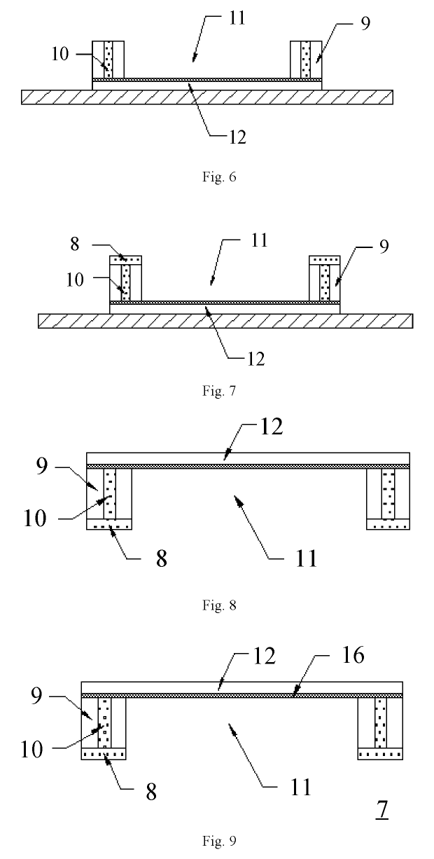

S106: after etching on the cylindrical ring of the substrate 9, the holes formed by etching are filled by a plating process, wherein the plated metal constitutes circuit 10. A bottom end of the circuit 10 is connected integrally with the electrode 16 (as shown in FIG. 6), and solder bumps 8 are plated extending along the surface of the substrate 9 at the top end of the plating (as shown in FIG. 7). In the MEMS chip manufacturing process flow, covering the electrode 16, covering the diaphragm 12, and then etching the back cavity of the substrate 9 are normal procedures for MEMS chip manufacturing. Moreover, since the diaphragm 12 is very thin, protective measures must be adopted during the process flow to protect the diaphragm 12, such as covering the surface of the diaphragm 12 with a polymer protective layer to prevent contamination or mechanical damage, which will not be further described in this embodiment. After peeling off the carrier board, the MEMS chip is completed (as shown in FIG. 8). The diaphragm 12 undergoes mechanical vibration when impacted by sound waves, causing changes in capacitance or other electrical values, and electrode 16 transmits the changed electrical values to the solder bumps 8 through the circuit 10.

By adding the plated circuit 10 and solder bumps 8 after substrate etching during the MEMS chip manufacturing process, the electrical properties of the MEMS chip are led from the electrode 16 on its front side (the side where the diaphragm 12 is located) to the solder bumps 8 on its back side. The MEMS chip is mounted through the solder bumps 8 to achieve electrical connection, providing better flexibility for MEMS chip mounting. By using the internal circuit 10 of the substrate 9 instead of wire bonding processes, the overall structure of the chip is more compact, satisfying the requirements for device miniaturization.

A MEMS chip packaging structure for an acoustic device can be obtained through the above-described MEMS chip packaging method for the acoustic device. As shown in FIG. 9, FIG. 9 is a cross-sectional view of the packaging structure, comprising a substrate 9, wherein the material of the substrate 9 is selected from one or more of flexible material, glass, or semiconductor material, and further comprising:

an electrode 16 and a diaphragm 12, wherein the electrode 16 is disposed above the substrate 9, the electrode 16 has a porous structure, the diaphragm 12 is disposed above the electrode 16, the pitch between the diaphragm 12 and the electrode 16 is approximately 1-5 μm, and the material of the diaphragm 12 is selected from one or more of polysilicon, silicon nitride, or metal;

a back cavity 11, wherein the back cavity 11 is formed by etching through from a central position of the surface of the substrate 9 away from the electrode 16 to expose the electrode 16, and the back cavity 11 is located directly below the diaphragm 12 and the electrode 16;

a circuit 10, wherein circuit hole is formed by etching through other portions of the substrate 9, and metal is plated to fill the circuit hole to form the circuit 10. One end of the circuit 10 is electrically connected to the electrode 16, and the other end of the circuit 10 is flush with and exposed at the surface of the substrate 9. Solder bumps 8 are plated extending on the surface of the substrate 9 where the circuit 10 is exposed, and the solder bumps 8 are electrically connected to the circuit 10.

The diaphragm 12 undergoes mechanical vibration when impacted by sound waves, causing changes in capacitance or other electrical values, and the electrode transmits the changed electrical values to the solder bumps 8 through the circuit 10.

The above-described MEMS chip packaging structure for the acoustic device is mounted to a working area, and the MEMS chip is electrically connected to other devices (such as an application-specific integrated circuit (ASIC) chip) to realize acoustic sensor functionality. The MEMS chip is electrically connected to electrical interface of the ASIC chip through the solder bumps 8 at the bottom of the substrate 9. The diaphragm 12 of the MEMS chip is in communication with the external environment, sound waves from the external environment are directed toward a central position above the diaphragm 12, and the back cavity 11 is aligned with a central position below the diaphragm 12. The ASIC chip may or may not be in communication with the external environment.

The working principle of a MEMS (Micro-Electro-Mechanical System) acoustic sensor is based on the conversion between mechanical vibration and electrical signals, wherein the core is converting sound waves (audio signals) into electrical signals through micro-mechanical structures. The core of the MEMS acoustic sensor is a micrometer-level diaphragm 12 suspended above the back cavity 11. An electrode 16 is disposed between the diaphragm 12 and the substrate 9, with the electrode 16 forming a capacitive structure. When sound waves from the external environment act on the diaphragm 12, the diaphragm 12 undergoes mechanical vibration with changes in sound pressure. The back cavity 11 is disposed directly below the diaphragm 12, providing vibration space and acoustic damping for the diaphragm 12 and regulating the mechanical response of the diaphragm 12. The mechanical vibration of the diaphragm 12 causes the distance between the electrode 16 and the substrate 9 to change, and the electrical value of the electrode 16 consequently changes, such as the capacitance value C. The capacitance value C is determined by the formula C=εA/d (where ε is the dielectric constant, A is the electrode area, and d is the plate pitch, wherein the plate pitch refers to the pitch between the electrode 16 and the substrate 9). Changes in the electrical value of the electrode 16 are transmitted through the circuit 10 and the solder bumps 8 to the ASIC chip electrically connected to the MEMS chip for processing. The application-specific integrated circuit (ASIC) integrated in the sensor is responsible for processing these changes in electrical values. The ASIC chip provides a bias voltage (DC voltage) for the capacitive structure, converting capacitance changes into charge changes, converting weak charges into voltage signals through a charge amplifier, and converting the analog voltage signals into digital signal output, thereby fulfilling the function of an acoustic sensor.

The embodiment of the present disclosure further provides an acoustic device comprising the above-described MEMS chip packaging structure for the acoustic device.

The beneficial effects of this embodiment are: by adding the plated circuit 10 and the solder bumps 8 connected to the circuit 10 after etching the substrate 9 during the MEMS chip manufacturing process, the electrical properties of the MEMS chip are led from the electrode 16 on its front side (the side where the diaphragm 12 is located) to the solder bumps 8 on its back side. The solder bumps 8 serve as a medium for mounting the MEMS chip to achieve electrical connection with other devices, providing better flexibility for MEMS chip mounting. The internal circuit 10 of the substrate 9 replaces wire bonding processes, making the overall structure of the chip more compact and satisfying the requirements for device miniaturization.

For ease of description, the above-mentioned MEMS chip is hereinafter referred to as a second device 7.

The packaging method for the MEMS acoustic device structure proposed by the present disclosure comprises the following steps:

mounting and encapsulating a first device 1: mounting the first device 1 on a carrier board, encapsulating the first device 1, and grinding the encapsulation surface until electrical interface is exposed;

electrically leading out the first device 1: plating a redistribution layer (RDL) 2 flat on the encapsulation surface, wherein a redistribution layer 2 is connected to the exposed electrical interface of the first device 1, and plating a conductive block 3 on a portion of the redistribution layer 2, continuing encapsulation and grinding to expose the top surface of the conductive block 3, wherein the encapsulation material constitutes a package body 4;

mounting and connecting the second device 7: electrically connecting the second device 7 to the conductive block 3 through the solder bumps 8 at the bottom of the substrate, with the second device 7 and the first device 1 stacked vertically;

mounting a substrate ring 13: mounting the substrate ring 13 on the package body 4 to surround the second device 7;

encapsulating with a cover plate 14: mounting the cover plate 14 on the substrate ring 13 to seal the substrate ring 13, wherein an acoustic hole in the cover plate 14 is aligned with a central position of the diaphragm 12 of the second device 7.

Generally, the above steps of this process can be summarized as the following five steps: manufacturing the second device 7, packaging the first device 1 (comprising mounting and encapsulating the first device 1 and electrically leading out the first device 1, etc.), mounting the first device 1 and the second device 7 (mounting and connecting the second device 7), mounting the substrate ring 13, and encapsulating with the cover plate 14.

Wherein the second device 7 is a MEMS chip, and the manufacturing process and specific structure of the second device 7 can be referred to the description of FIGS. 1 to 11, which will not be repeated here.

Wherein the first device 1 is an ASIC chip, which is encapsulated within the package body 4, and the manufacturing steps of the first device 1 are specifically as follows:

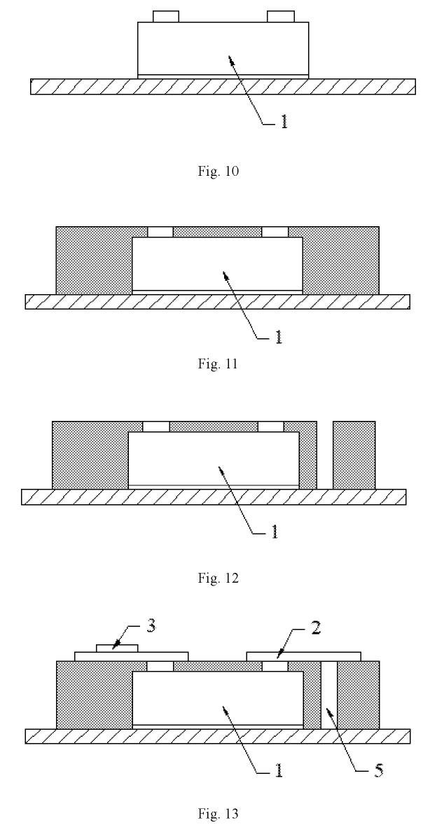

S201: providing a carrier board, which may be a resin board commonly used in the art, placing the first device 1 on the carrier board (as shown in FIG. 10), wherein the front side of the first device 1 has electrical interface, and the back side of the first device 1 is mounted on the carrier board.

S202: using encapsulation material to encapsulate the first device 1 on the carrier board, and horizontally grinding the encapsulation top surface by mechanical grinding until the electrical interface on the front side of the first device 1 are exposed (as shown in FIG. 11).

S203: vertically etching the encapsulation material at corresponding positions on the encapsulation top surface to form drilled hole until the surface of the carrier board is exposed (as shown in FIG. 12).

S204: plating a metal pillar 5 by a plating process to fill the drilled hole, wherein a bottom end of the metal pillar 5 contacts the carrier board, and plating a redistribution layer (RDL) 2 horizontally flat along the encapsulation top surface. The redistribution layer 2 is respectively connected to the exposed electrical interface of the first device 1, and the conductive block 3 is plated on a portion of the redistribution layer 2 (as shown in FIG. 13). Another portion of the redistribution layer 2 is electrically connected to the top end of the metal pillar 5. The electrical properties of the first device 1 are transmitted from the electrical interface through the redistribution layer 2 to the bottom end of the metal pillar 5. The electrical properties of the first device 1 are electrically connected through the electrical interface, the redistribution layer 2, and the conductive block 3.

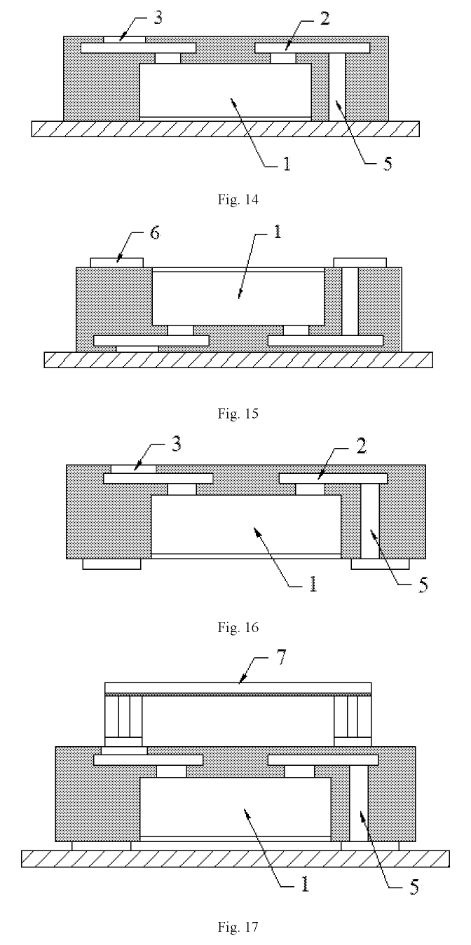

S205: continuing to use encapsulation material to encapsulate on the encapsulation top surface in S202, encapsulating the respective redistribution layers 2, conductive block 3, and metal pillar 5 within the encapsulation material, and likewise horizontally grinding the encapsulation top surface of the new encapsulation by mechanical grinding until the top surface of the conductive block 3 is exposed (as shown in FIG. 14). The conductive block 3 serve as electrical connection terminals between the first device 1 and the second device 7, and their quantity and layout are set according to the electrical connection relationship between the second device 7 and the first device 1 of the actual product.

S206: peeling the entire encapsulation from the carrier board, flipping it over, and remounting it on the carrier board, such that the exposed conductive block 3 is in contact with the carrier board, and the bottom end of the exposed metal pillar 5 is exposed. External pins 6 are plated at corresponding positions on this surface of the entire encapsulation, wherein a portion of the external pins 6 are electrically connected to the exposed metal pillar 5 (as shown in FIG. 15).

S207: after the plating is completed, peeling the entire encapsulation from the carrier board to obtain the package body 4 of the first device 1 (as shown in FIG. 16). For cases where multiple first devices 1 are mounted on the carrier board at one time and the process flow simultaneously processes multiple first devices 1, a cutting process is finally required, that is, cutting the encapsulation material at the cutting street position in the safe area of the entire encapsulation, thereby separating the package body 4 of each first device 1 into product units. The present disclosure takes the case of processing the encapsulation of one first device 1 as an example.

Encapsulating the first device 1 within the package body 4 protects the ASIC chip from erosion by the external environment and extends service life. The back side of the first device 1 is exposed outside the package body 4 through adhesive glue, enhancing heat dissipation performance.

The specific mounting steps for the first device 1 and the second device 7 are as follows:

S301: placing the package body 4 back onto a carrier board via the external pins 6, and stacking the two devices by aligning a solder pad 8 of the second device 7 with the exposed conductive block 3 of the package body 4 (as shown in FIG. 17); soldering the solder pad 8 of the second device 7 to the exposed conductive block 3 of the package body 4 through reflow soldering to form an integrated structure, thereby achieving electrical connection between the two devices; wherein the diaphragm 12 of the second device 7 undergoes mechanical vibration when impacted by sound waves, causing changes in capacitance or other electrical values, and the electrode transmits the changing electrical values to the solder pad 8 through the circuit 10, and the solder pad 8 transmit the signals to the first device 1 for processing via the conductive block 3 and the redistribution layer 2, such as signal amplification, filtering, and analog-to-digital conversion (ADC); wherein, depending on the specific product structure and functions, the electrical connection relationship between the first device 1 and the second device 7 is laid out, and accordingly, the circuit 10 and the solder pad 8 of the second device 7, as well as the number and positions of the conductive block 3 and the redistribution layer 2 of the first device 1 are laid out; for example, to add clock or synchronization signal capabilities, where the ASIC requires synchronous sampling (such as in a digital microphone), a clock signal may be provided to the MEMS to coordinate operations, requiring an additional electrical connection relationship between the first device 1 and the second device 7 to implement this function; wherein the accompanying drawings are all cross-sectional views showing only the electrical connection relationships presented in these cross-sectional views, and other necessary electrical connection relationships between the ASIC chip and the MEMS chip are also within the protection scope of the present disclosure.

The present disclosure separately processes the first device 1 and the second device 7 and then mounts and stacks them together; the first device 1 and the second device 7 can be individually pre-fabricated without affecting each other, resulting in higher overall processing efficiency; the present disclosure takes the example of processing the second device 7 first and then processing the first device 1; by soldering the solder pad 8 of the second device 7 onto the conductive block 3 of the package body 4 of the first device 1, stacking of the two devices is achieved without using a wire bonding process, saving stacking space, and the overall structure has high integration, smaller size, good structural stability, and more stable and reliable line transmission.

The structural dimensions of MEMS chips and ASIC chips often differ significantly; by plating the redistribution layer 2 and the conductive block 3 within the package body 4, the electrical interface of the ASIC chip are re-laid out to accommodate the dimensions of the MEMS chip, ensuring that the MEMS chip is stacked and mounted on the conductive block 3 of the ASIC chip via the solder pad 8 at the bottom of the substrate 9 to achieve electrical interconnection; the overall sensor dimensions meet miniaturization requirements, with a compact and reasonably laid out structure.

The specific steps for mounting the substrate ring 13 and encapsulating the cover plate 14 are as follows:

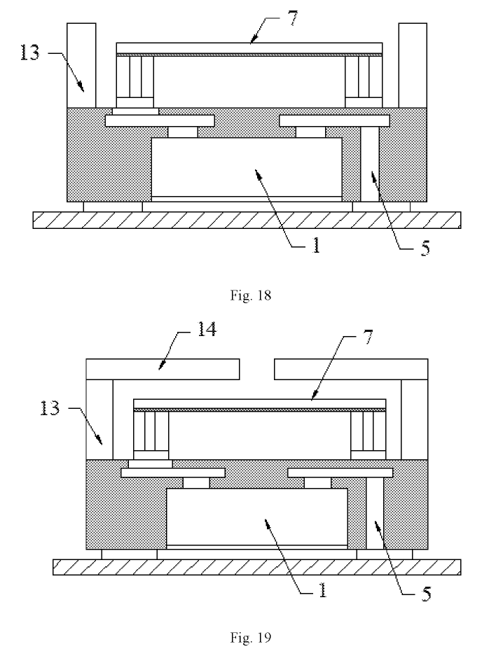

S401: mounting the substrate ring 13 on the package body 4 to enclose the second device 7 therein (as shown in FIG. 18), wherein the side surface of the substrate ring 13 is flush with the side surface of the package body 4 of the second device 7, and the substrate ring 13 is configured along the surface shape of the package body 4; the substrate ring 13 is a printed circuit board (PCB), and the reasons for adopting a PCB comprise, on one hand, its low cost and mature process, and on the other hand, the convenience of direct connection between the PCB and the package body 4, which can be achieved by adhesive or the like for connection and mounting; the height of the substrate ring 13 is greater than the height of the second device 7, allowing the second device 7 to be enclosed within the substrate ring 13.

S402: mounting the cover plate 14 on the substrate ring 13, wherein the side surface of the cover plate 14 is also flush with the side surface of the substrate ring 13 (as shown in FIG. 19); the cover plate 14 and the substrate ring 13 are connected and mounted by adhesive or the like to seal the substrate ring 13; the cover plate 14 is provided with an acoustic hole 15, which is aligned with a central position of the diaphragm 12 of the second device 7; the diaphragm 12 is aligned with a central position of the back cavity 11 of the second device 7; the three are vertically arranged; and the diaphragm 12 is in communication with the external environment through the acoustic hole 15.

The working principle of MEMS (Micro-Electro-Mechanical System) acoustic sensors (such as MEMS microphones) is based on the conversion between mechanical vibration and electrical signals, and its core is to convert sound waves (audio signals) into electrical signals through micro-mechanical structures; the core of the MEMS acoustic sensor is a micrometer-scale diaphragm 12 suspended above the back cavity 11; electrodes are disposed between the diaphragm 12 and the substrate 9, forming a capacitive structure; the substrate ring 13 and the cover plate 14 encapsulate and protect the MEMS chip; the cover plate 14 is provided with an acoustic hole 15, which is vertically aligned with the center of the diaphragm 12 of the MEMS chip; when sound waves (air vibrations) act on the diaphragm 12 through the acoustic hole 15, the diaphragm 12 undergoes mechanical vibration with changes in sound pressure; the back cavity 11 of the substrate 9 provides vibration space and acoustic damping, regulating the mechanical response of the diaphragm 12; the mechanical vibration of the diaphragm 12 causes changes in the distance between the electrode and the substrate 9, resulting in changes in the electrical values of the electrode, such as the capacitance value C, which is determined by the formula C=εA/d (where ε is the permittivity, A is the electrode area, and d is the distance between the plates, wherein the plates refer to the electrode and the substrate 9); the changes in the electrical values of the electrode are transmitted to the ASIC chip through the circuit 10, the solder pad 8, the conductive block 3, and the redistribution layer 2; the present disclosure may also reduce or increase corresponding components as long as the electrical connection relationship between the ASIC chip and the MEMS chip can be achieved, which is also within the protection scope of the present disclosure; the application-specific integrated circuit (ASIC) integrated in the sensor is responsible for processing these changes in electrical values; the ASIC chip is integrated inside the sensor to reduce noise interference and improve sensitivity; the ASIC chip provides a bias voltage (DC voltage) for the capacitive structure to convert capacitance changes into charge changes, and converts weak charges into voltage signals through a charge amplifier, converting analog voltage signals into digital signals for output; the ASIC chip does not need to directly interact with the environment and is encapsulated within the package body 4, encapsulated by molding compound to protect it from moisture, dust, and mechanical stress; no additional protective structure is required after packaging, resulting in higher overall integration of the sensor; the ASIC chip leads out its electrical properties to the outside of the package body 4 through the redistribution layer 2, the metal pillar 5, and the external pins 6; the external pins 6 serve as a connecting bridge between the external electrical properties of the sensor working area and the internal electrical properties of the ASIC chip within the package body 4; of course, other structures implementing internal electrical connection within the package body 4 are also within the protection scope of the present disclosure.

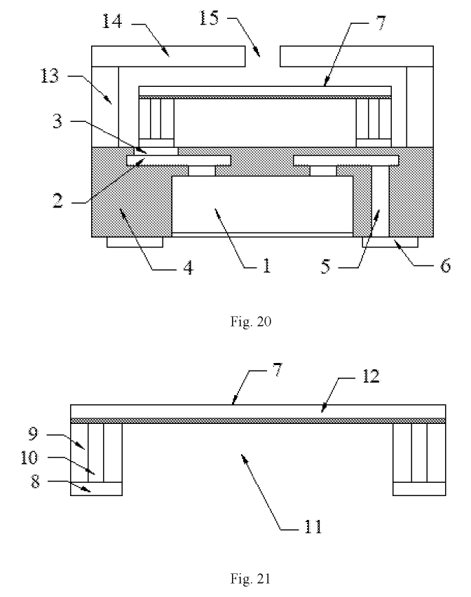

The above-described packaging method for the MEMS acoustic device structure can yield a MEMS acoustic device package structure. As shown in FIG. 20, FIG. 20 is a cross-sectional view of the package structure, comprising the first device 1 and the second device 7, and further comprising:

a package body 4, wherein the first device 1 is encapsulated within the package body 4, and the first device 1 is an ASIC chip;

a redistribution layer 2 and conductive block 3, wherein the redistribution layer 2 connected to electrical interface of the first device 1 is plated in a planar manner within the package body 4, and the conductive block 3 are plated on a portion of the redistribution layer 2; the top surface of the conductive block 3 are flush with and exposed from the top surface of the package body 4; the structural dimensions of MEMS chips and ASIC chips often differ significantly; by plating the redistribution layer 2 and the conductive block 3 within the package body 4, the electrical interface of the ASIC chip are re-laid out to accommodate the dimensions of the MEMS chip, ensuring that the MEMS chip is stacked and mounted on the conductive block 3 of the ASIC chip via the solder pad 8 at the bottom of the substrate 9 to achieve electrical interconnection; the overall sensor dimensions meet miniaturization requirements, with a compact and reasonably laid out structure.

Before plating the redistribution layer 2 within the package body 4, vertically etching the encapsulant to the bottom surface of the package body 4, and plating metal pillar 5 to completely fill the drilled hole; the top end of the metal pillar 5 is electrically connected to another portion of the redistribution layer 2; the electrical properties of the first device 1 are transmitted from the electrical interface through the redistribution layer 2 to the bottom end of the metal pillar 5; the bottom end of the metal pillar 5 is flush with and exposed from the bottom surface of the package body 4; plating external pins 6 on the bottom surface of the package body 4 where the metal pillar 5 is exposed; the bottom end of the metal pillar 5 is electrically connected to portions of the external pins 6; and the external pins 6 serve as a connecting bridge between the external electrical properties of the sensor working area and the internal electrical properties of the ASIC chip within the package body 4.

The second device 7 is mounted on the exposed conductive block 3 of the package body 4 via the solder pad 8 at the bottom of the substrate 9, achieving vertical stacking and electrical interconnection between the second device 7 and the first device 1; electrodes are covered above the substrate 9 of the second device 7, and the diaphragm 12 is covered above the electrodes; the material of the substrate 9 of the second device 7 is selected from one or more of flexible materials, glass, and semiconductor materials; the substrate 9 is located at the bottommost layer of the second device 7, serving as mechanical support for the entire structure, providing structural stability, and serving as a base for other components such as the electrodes and the back cavity 11; the material of the diaphragm 12 is selected from one or more of polysilicon, silicon nitride, and metal; the thickness of the diaphragm 12 is extremely thin, ranging from nanometers to micrometers, sensitive to sound pressure, with its vibration displacement being proportional to sound pressure, and serving as the core sensitive element of the sensor.

The middle portion of the substrate 9 of the second device 7 is etched through to form the back cavity 11, which is located directly below the diaphragm 12; the structure of the back cavity 11 allows the diaphragm 12 to vibrate freely under the action of sound pressure, avoiding air damping, and can balance the pressure on both sides of the diaphragm 12; the circuit 10 is disposed inside the substrate 9 of the second device 7; the top end of the circuit 10 is connected with the electrodes, and the bottom end of the circuit 10 is electrically connected to the solder pad 8 at the bottom of the substrate 9; and the solder pad 8 of the second device 7 are soldered to the top surface of the exposed conductive block 3 of the package body 4 through reflow soldering.

By adding the plating of the circuit 10 and the solder pad 8 after etching the substrate 9 during the manufacturing process of the second device 7, the electrical properties of the second device 7 are routed from the electrodes on its front side (the side where the diaphragm 12 is located) to the solder pad 8 on its back side, providing better mounting flexibility for the second device 7 and a compact structure.

The diaphragm 12 generates mechanical vibrations, causing changes in electrical values, and sequentially transmits signals to the first device 1 for processing via the electrode, the circuit 10, the solder pad 8, the conductive block 3, and the redistribution layer 2, wherein the second device 7 is a MEMS chip.

a substrate ring 13, wherein the substrate ring 13 is mounted on the package body 4 to enclose the second device 7 therein;

a cover plate 14, wherein the cover plate 14 is mounted on the substrate ring 13 to seal the substrate ring 13, the acoustic hole 15 in the cover plate 14 is aligned with a central position of the diaphragm 12 of the second device 7, and the substrate ring 13 and the cover plate 14 are adhered by adhesive;

In this structure, the substrate ring 13 and the cover plate 14 encapsulate and protect the MEMS chip; the cover plate 14 is provided with an acoustic hole 15, which is vertically aligned with the center of the diaphragm 12 of the MEMS chip; when sound waves (air vibrations) act on the diaphragm 12 through the acoustic hole 15, the diaphragm 12 undergoes mechanical vibration with changes in sound pressure; the back cavity 11 of the substrate 9 provides vibration space and acoustic damping, regulating the mechanical response of the diaphragm 12; the mechanical vibration of the diaphragm 12 causes changes in the distance between the electrode and the substrate 9, resulting in changes in the electrical values of the electrode; the changes in the electrical values of the electrode are transmitted to the ASIC chip through the circuit 10, the solder pad 8, the conductive block 3, and the redistribution layer 2; the ASIC chip processes changes in electrical values such as capacitance values and amplifies the signals; the ASIC chip is integrated inside the sensor and encapsulated within the package body 4, encapsulated by molding compound to protect it from moisture, dust, and mechanical stress; and the ASIC chip leads out its electrical properties to the outside of the package body 4 through the redistribution layer 2, the metal pillar 5, and the external pins 6.

The beneficial effects of this embodiment are:

By adding the plating of the circuit 10 and the solder pad 8 after etching the substrate 9 during the manufacturing process of the second device 7, the electrical properties of the second device 7 are routed from the electrode on its front side (the side where the diaphragm 12 is located) to the solder pad 8 on its back side, providing better mounting flexibility for the second device 7.

Encapsulating the first device 1 within the package body 4 protects the ASIC chip from erosion by the external environment, extending its service life, and the back side of the first device 1 is exposed outside the package body 4 through adhesive, enhancing heat dissipation performance.

The first device 1 and the second device 7 are separately processed and then mounted and stacked together, and the first device 1 and the second device 7 can be individually pre-fabricated without affecting each other, resulting in higher overall processing efficiency.

By soldering the solder pad 8 of the second device 7 onto the conductive block 3 of the package body 4 of the first device 1, stacking of the two devices is achieved without using a wire bonding process, saving stacking space, and the overall structure has high integration, smaller size, good structural stability, and more stable and reliable line transmission.

In all encapsulation steps of the present disclosure, the encapsulant used is a molding compound, specifically made of materials such as epoxy resin, cyanate ester, polyimide, or the like, which are low in cost and have good curing properties; the packaging method plays an important role in the semiconductor manufacturing field, mainly manifested in protection, connection, support, reliability, and promoting technological progress; and the encapsulation method is transfer molding or the like commonly used in the art.

In all post-encapsulation grinding processes of the present disclosure, grinding machines commonly used in the technical field are used for surface treatment of the encapsulated surface, that is, horizontal mechanical grinding is performed on the top surface of the encapsulation, and finally the ground surface is horizontally flat and smooth, with the outer surface of the entire package structure being flat and smooth.

In all steps employing an electroplating process in the present disclosure, a photoresist film is first used to form plating protection on a surface through photolithography technology involving exposure and development, thereby protecting areas that do not require plating with the photoresist film and exposing regions that require plating. Subsequently, a metal seed layer is formed in the areas to be plated through appropriate methods such as sputtering or copper deposition. The metal seed layer is made of copper or other metallic materials, and serves to ensure adhesion between the metal to be subsequently plated and existing metal, as well as between the metal and the encapsulant, while also providing a surface for the attachment of conductive ions to ensure the electroplating effect. The entire procedure of the electroplating process and the materials used therein are also common technical knowledge in the art, and the metal plated in all electroplating processes of the present disclosure is copper.

It should be understood that the present disclosure is described through certain embodiments, and those skilled in the art know that various changes or equivalent substitutions may be made to these features and embodiments without departing from the spirit and scope of the present disclosure. Furthermore, under the teaching of the present disclosure, these features and embodiments may be modified to adapt to specific situations and materials without departing from the spirit and scope of the present disclosure. Therefore, the present disclosure is not limited to the specific embodiments disclosed herein, and all embodiments falling within the scope of the claims of the present disclosure belong to the scope protected by the present disclosure.

What is claimed is:

1. A packaging method for a MEMS acoustic device structure, comprising steps of:
first device encapsulation: encapsulating a first device and exposing an electrical interface, plating a redistribution layer on an encapsulation surface to be connected with the electrical interface, plating a conductive block on a portion of the redistribution layer, and encapsulating and exposing a top surface of the conductive block to form a package body;
second device interconnection: electrically connecting a second device to the conductive block, with the second device and the first device being vertically stacked and connected;
substrate ring mounting: mounting a substrate ring on the package body to enclose the second device;
cover plate packaging: mounting a cover plate to seal the substrate ring, with an acoustic hole of the cover plate aligned with a middle portion of a diaphragm of the second device.

2. The packaging method for a MEMS acoustic device structure according to claim 1, wherein, in the step of first device encapsulation, the first device is placed on a carrier board, and before plating the redistribution layer on an encapsulation top surface exposing the electrical interface after encapsulating the first device, encapsulation material is vertically etched to a bottom of a drilled hole to expose the carrier board, and a metal pillar is plated to completely fill the drilled hole.

3. The packaging method for a MEMS acoustic device structure according to claim 2, wherein, in the step of first device encapsulation, a top end of the metal pillar is electrically connected to another portion of the redistribution layer, a bottom end of the metal pillar is in contact with the carrier board, and the first device is electronically connected to the bottom end of the metal pillar by the electrical interface through the redistribution layer.

4. The packaging method for a MEMS acoustic device structure according to claim 3, wherein, in the step of first device encapsulation, the bottom end of the metal pillar is flush with and exposed from a bottom surface of the package body, external pins are plated on a bottom surface of the package body where the metal pillar is exposed, and the bottom end of the metal pillar is electrically connected to portions of the external pins.

5. The packaging method for a MEMS acoustic device structure according to claim 1, wherein, in the step of first device encapsulation, after encapsulating with encapsulation material, the encapsulation surface is horizontally mechanically ground to respectively expose the electrical interface and the conductive block.

6. The packaging method for a MEMS acoustic device structure according to claim 1, wherein, in the step of second device interconnection, an electrode is covered above a substrate of the second device, and a diaphragm is covered above the electrode.

7. The packaging method for a MEMS acoustic device structure according to claim 6, wherein, in the step of second device interconnection, a pitch between the diaphragm and the electrode is 1-5 μm.

8. The packaging method for a MEMS acoustic device structure according to claim 6, wherein, in the step of second device interconnection, a material of the substrate is selected from one or more of flexible materials, glass, and semiconductor materials; and/or a material of the diaphragm is selected from one or more of polysilicon, silicon nitride, and metals.

9. The packaging method for a MEMS acoustic device structure according to claim 6, wherein, in the step of second device interconnection, a middle portion of the substrate of the second device is etched through to form a back cavity located directly below the diaphragm, a circuit is provided inside the substrate of the second device, a solder pad is provided at a bottom of the substrate, a top end of the circuit is electrically connected to the electrode, and a bottom end of the circuit is electrically connected to the solder pad.

10. The packaging method for a MEMS acoustic device structure according to claim 9, wherein, in the step of second device interconnection, the solder pad of the second device is soldered to an exposed top surface of the conductive block of the package body by reflow soldering to form an integrated structure.

11. The packaging method for a MEMS acoustic device structure according to claim 10, wherein, in the step of second device interconnection, the diaphragm of the second device generates mechanical vibration, causing an electrical value change, which is transmitted sequentially through the electrode, the circuit, the solder pad, the conductive block, and the redistribution layer to the first device for signal processing.

12. The packaging method for a MEMS acoustic device structure according to claim 1, wherein, in the step of first device encapsulation, the first device is an ASIC chip; and/or in the step of second device interconnection, the second device is a MEMS chip.

13. A MEMS acoustic device packaging structure, comprising a first device and a second device, and further comprising:
a redistribution layer plated inside a package body and connected to an electrical interface, a conductive block plated on a portion of the redistribution layer, with a top surface of the conductive block flush with and exposed from the package body;
a substrate ring mounted on the package body to enclose the second device; and
a cover plate mounted to seal the substrate ring, with an acoustic hole of the cover plate aligned with a middle portion of a diaphragm of the second device,
wherein the first device is encapsulated in the package body, and the second device is electrically connected to the conductive block, so as to be vertically stacked and connected with the first device.

14. A MEMS chip packaging method for an acoustic device, comprising steps of:
substrate etching: an electrode being provided above a substrate, a diaphragm being provided above the electrode, etching through from a middle position of a surface of the substrate away from the electrode to form a back cavity, so as to expose the electrode, with the back cavity located directly below the electrode;
simultaneously etching through other portions of the substrate to form a circuit hole exposing the electrode;
circuit plating: plating and filling metal in the circuit hole to form a circuit, with one end of the circuit electrically connected to the electrode and the other end of the circuit flush with and exposed from the surface of the substrate.

15. The MEMS chip packaging method for an acoustic device according to claim 14, wherein, in the step of substrate etching, a material of the substrate is selected from one or more of flexible materials, glass, and semiconductor materials.

16. The MEMS chip packaging method for an acoustic device according to claim 14, wherein, in the step of substrate etching, an electrode is covered on the substrate, and the electrode has a porous structure.

17. The MEMS chip packaging method for an acoustic device according to claim 16, wherein, in the step of substrate etching, a diaphragm is covered on the electrode, and a pitch between the diaphragm and the electrode is 1-5 μm.

18. The MEMS chip packaging method for an acoustic device according to claim 17, wherein, in the step of substrate etching, a material of the diaphragm is selected from one or more of polysilicon, silicon nitride, and metals.

19. The MEMS chip packaging method for an acoustic device according to claim 14, wherein, in the step of circuit plating, a solder pad is extendedly plated on the surface of the substrate where the circuit is exposed, and the solder pad is electrically connected to the circuit.

20. The MEMS chip packaging method for an acoustic device according to claim 14, wherein, in the step of circuit plating, the diaphragm generates mechanical vibration, causing an electrical value change, which is transmitted sequentially through the electrode, the circuit, and the solder pad.
